(19) United States
(12) Patent Application Publication
(10) Pub. No.: US 2003/0155079 A1
(43) Pub. Date: Aug. 21, 2003

(54) PLASMA PROCESSING SYSTEM WITH DYNAMIC GAS DISTRIBUTION CONTROL

(76) Inventors: ANDREW D. BAILEY III, PLEASANTON, CA (US); ALAN M. SCHOEPP, BEN LOMOND, CA (US); DAVID J. HEMKER, SAN JOSE, CA (US); MARK H. WILCOXSON, PIEDMONT, CA (US)

Correspondence Address: BEYER WEAVER & THOMAS LLP, P.O. BOX 778, BERKELEY, CA, 94704-0778, US

(21) Appl. No.: 09/470,236

(22) Filed: Nov. 15, 1999

(51) Int. Cl. H01L 21/306; C23C 16/00

(52) U.S. Cl. 156/345.49; 156/345.29; 156/345.48; 118/715; 118/723 I

(57) ABSTRACT

A plasma processing system that includes a plasma processing chamber that provides enhanced control over an etch process is disclosed. The plasma processing chamber is connected to a gas flow system. The gas flow system can be employed to control the release of gases into different regions within the plasma processing chamber. In addition, the volume of the released gas, e.g., the flow rate of the gas, can be adjusted by a gas flow control mechanism. In this manner, both the position and the amount of the gas that is delivered to the plasma processing chamber can be controlled. The ability to adjust the position and the amount of gas that is released into the plasma processing chamber provides for a better control over the distribution of the neutral components. This in turn enhances control over the etching process.

### CROSS-REFERENCE TO RELATED CASES

This application is related to following concurrently filed U.S. patent applications:

i) Application Ser. No.: ______ entitled “IMPROVED PLASMA PROCESSING SYSTEMS AND METHODS THEREFOR”. (Attorney Docket No.: LAM1P0122/P0527)

ii) Application Ser. No.: ______ entitled “TEMPERATURE CONTROL SYSTEM FOR PLASMA PROCESSING APPARATUS”; (Attorney Docket No.: LAM1P0124/P0558)

iii) Application Ser. No.: ______ entitled “METHOD AND APPARATUS FOR PRODUCING UNIFORM PROCESS RATES”, (Attorney Docket No.: ______ LAM1P0125/P0560)

iv) Application Ser. No.: ______ entitled “MATERIALS AND GAS CHEMISTRIES FOR PLASMA PROCESSING SYSTEMS”, (Attorney Docket No.: LAM1P0128/P0561-1)

v) Application Ser. No.: ______ entitled “METHOD AND APPARATUS FOR CONTROLLING THE VOLUME OF PLASMA”, (Attorney Docket No.: LAM1P0129/P0561-2)

Each of the above-identified patent applications is incorporated herein by reference.

### BACKGROUND OF THE INVENTION

1. Field of the Invention

The present invention relates to fabrication of semiconductor integrated circuits and, more particularly, to improved plasma processing systems for enhancing etch processes.

2. Description of the Related Art

In the fabrication of semiconductor-based devices, e.g., integrated circuits or flat panel displays, layers of materials may alternately be deposited onto and etched from a substrate surface. During the fabrication process, various layers of material, e.g., borophosphosilicate glass (BPSG), polysilicon, metal, etc., are deposited on the substrate. The deposited layers may be patterned with known techniques, e.g., a photoresist process. Thereafter, portions of the deposited layers can be etched away to form various features, e.g., interconnect lines, vias, trenches, and etc.

The process of etching may be accomplished by a variety of known techniques, including plasma-enhanced etching. In plasma-enhanced etching, the actual etching typically takes place inside a plasma processing chamber. To form the desired pattern on the substrate wafer surface, an appropriate mask (e.g., a photoresist mask) is typically provided. With the substrate wafer in the plasma processing chamber, a plasma is then formed from suitable etchant source gas (or gases). The plasma is used to etch areas that are left unprotected by the mask, thereby forming the desired pattern. in this manner, portions of deposited layers are etched away to form interconnect lines, vias, trenches, and other features. The deposition and etching processes may be repeated until the desired circuit is obtained.

To facilitate discussion, FIG. 1 depicts a simplified plasma processing apparatus 100 suitable for fabrication of semiconductor-based devices. The simplified plasma processing apparatus 100 includes a plasma processing chamber 102 having an electrostatic chuck (ESC) 104. The chuck 104 acts as an electrode and supports a wafer 106 (i.e., substrate) during fabrication. The surface of the wafer 106 is etched by an appropriate etchant source gas that is released into the wafer processing chamber 102. The etchant source gas can be released through a showerhead 108. The plasma processing source gas may also be released by other mechanisms such as through holes in a gas distribution plate. A vacuum plate 110 maintains a sealed contact with walls 112 of the wafer processing chamber 102. Coils 114 provided on the vacuum plate 110 are coupled to a radio frequency (RF) power source (not shown) and used to strike (ignite) a plasma from the plasma processing source gas released through the showerhead 108. The chuck 104 is also typically RF powered during the etch processes using a RF power supply (not shown). A pump 116 is also included to draw the process gases and gaseous products from the plasma processing chamber 102 through a duct 118.

As is known by those skilled in the art, in the case of etch processes, a number of parameters within the plasma processing chamber are tightly controlled to maintain high tolerance etch results. Gas composition, plasma excitation, and chamber conditions are process parameters that effect etch results. Since the etch tolerance (and resulting semiconductor-based device performance) is highly sensitive to such process parameters, accurate control thereof is required. To further elaborate, the etching process needs to be tightly controlled to achieve desirable etch characteristics, e.g., selectivity, etch uniformity, etch rate, etch profile, etc. Moreover, in modern integrated circuits controlling the etching process has gained even more significance. By way of example, as the features of modern integrated circuits have reduced in size, it has become increasingly more difficult to etch the desired features using conventional plasma processing systems with conventional methods. Thus, even tighter control of the etching process is needed for fabrication of modern integrated circuits.

In view of foregoing, there is a need for improved plasma processing systems that provide better control over the etching process.

### SUMMARY OF THE INVENTION

Broadly speaking, the invention pertains to improved techniques for etch processing in a plasma processing system. In accordance with one aspect, the present invention can be utilized to enhance control of the etching process by a plasma processing system that includes a plasma processing chamber. The plasma processing chamber is connected to a gas flow system. The gas flow system can be employed to control the release of gases into the plasma processing chamber to multiple, different locations. Moreover, the gas flow system enables the control over the amount, volume or relative flow of gas released into the plasma processing chamber.

The invention can be implemented in numerous ways, including as a system, apparatus, machine, or method. Several embodiments of the invention are discussed below.

As a plasma processing system, one embodiment of the invention includes: a plasma processing chamber used to process a substrate; and a gas flow system coupled to the plasma processing chamber. The gas flow system controls flow of input gas into at least two different regions of the plasma processing chamber. As examples, at least two different regions can be selected from a top central region, an upper peripheral region, and a lower peripheral region.

As a plasma processing system, another embodiment of the invention includes: a substantially azimuthally symmetric cylindrical plasma processing chamber within which a plasma is both ignited and sustained for the processing, the plasma processing chamber having no separate plasma generation chamber, the plasma processing chamber having an upper end and a lower end; a coupling window disposed at an upper end of the plasma processing chamber; an RF antenna arrangement disposed above a plane defined by the substrate when the substrate is disposed within the plasma processing chamber for the processing; an electromagnet arrangement disposed above the plane defined by the substrate, the electromagnet arrangement being configured so as to result in a radial variation in the static magnetic field topology within the plasma processing plasma processing chamber and the second region being a peripheral region of the plasma processing chamber.

This invention has numerous advantages. Among other things, the present invention operates to enhance control over the distribution, e.g., uniformity of distribution of the neutral components. in addition, the present invention can be utilized to gain more control over the etch process without having to unnecessarily limit certain other parameters of the etch process, e.g., pressure, power deposition, material used in the etch process. Furthermore, the present invention provides the flexibly to vary the distribution of neutral components. The distribution of neutral components can be adjusted for different etch processes, as well as during different stage of the same etching process.

Other aspects and advantages of the invention will become apparent from the following detailed description, taken in conjunction with the accompanying drawings illustrating, by way of example, the principles of the invention.

### BRIEF DESCRIPTION OF THE DRAWINGS

The present invention will be readily understood by the following detailed description in conjunction with the accompanying drawings, wherein like reference numerals designate like structural elements, and in which:

FIG. 1 illustrates a plasma processing system suitable for etching a substrate.

FIG. 2 illustrates a plasma processing system including a gas flow system in accordance with one embodiment of the present invention.

FIG. 3 illustrates a plasma processing system including a gas flow system in accordance with another embodiment of the present invention.

FIG. 4 illustrates a plasma processing system including a gas flow system in accordance with yet another embodiment of the present invention.

FIG. 5 illustrates a plasma processing system including a magnetic arrangement in conjunction with a gas flow system in accordance with a particular embodiment of the present invention.

### DETAILED DESCRIPTION OF THE INVENTION

This invention pertains to improved apparatus and methods for etch processing in a plasma processing system. The invention enables improved control over injection of process gases into a plasma processing chamber. As a result, greater control over etch processing can be achieved which is becoming more and more important as feature sizes continue to get smaller. The invention also leads to reduction in defects on processed substrates and thus greater manufacturing yields.

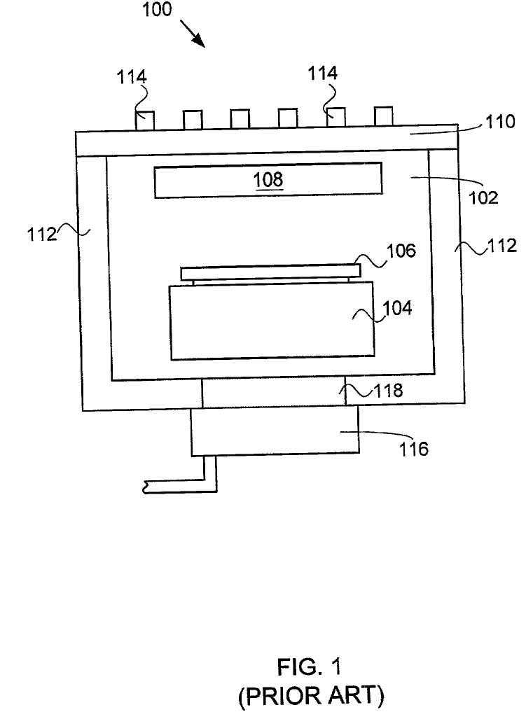

Embodiments of this aspect of the invention are discussed below with reference to FIGS. 1-5. However, those skilled in the art will readily appreciate that the detailed description given herein with respect to these figures is for explanatory purposes as the invention extends beyond these limited embodiments.

In one embodiment, a plasma processing system that includes a plasma processing chamber is disclosed. The plasma processing chamber is connected to a gas flow system. The gas flow system can be employed to control the release of gases into the plasma processing chamber. Input gas is received and delivered by the gas flow system to the plasma processing chamber. In accordance with a particular embodiment, input gas is delivered by two or more gas outlets of the gas flow system to the plasma processing chamber. Each gas outlet can deliver gas to a different desired region within the plasma processing system. In addition, the volume of the released gas, e.g., the flow rate of the gas, can be adjusted by the gas flow system. In this manner, both the position and the amount of the gas that is delivered into the plasma processing chamber can be controlled. The ability to adjust the position and the amount of gas that is released into the plasma processing chamber provides for better process control.

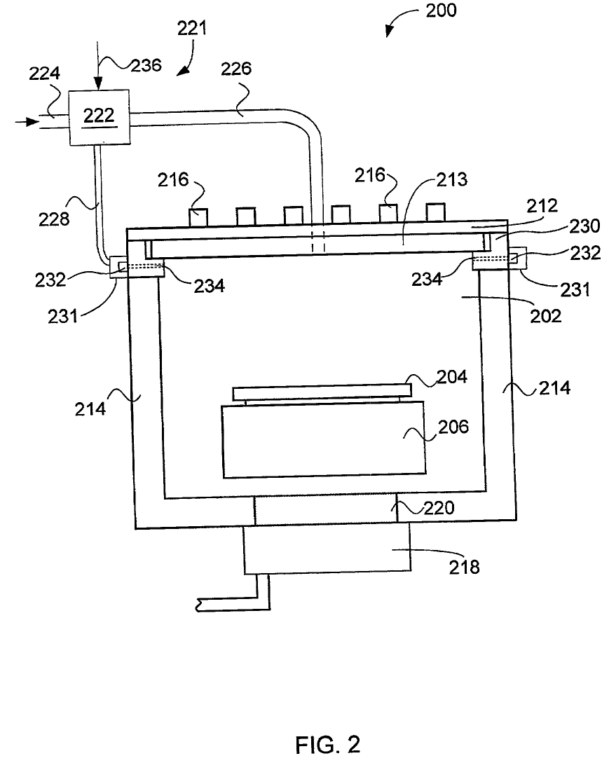

In semiconductor fabrication, features may be formed on a semiconductor wafer or substrate. More particularly, successive layers of various materials may be deposited on the semiconductor wafer or substrate. Thereafter, portions of selected deposited layers are etched away to form interconnect lines, trenches, and other features. To facilitate understanding of the present invention, FIG. 2 illustrates a plasma processing system 200 in accordance with one embodiment of the invention. The plasma processing system 200 includes a plasma processing chamber 202 having a wafer support mechanism, e.g., an electrostatic chuck (ESC) 206. A wafer (substrate) 204 is placed on the electrostatic chuck (ESC) 206 inside the plasma processing chamber 202. The ESC 206 can also be referred to as a bottom electrode that can be connected to a Radio Frequency (RF) powered source (not shown).

The surface of the wafer 206 is etched by an appropriate plasma processing source gas that is released into the plasma processing chamber 202. The source gas can be a single gas or a mixture of gases. The manner in which the plasma processing source gas is released into the plasma processing chamber 202 is discussed in more detail below. A vacuum plate 212 maintains a sealed contact with walls 214 of the wafer processing chamber 202. Coils 216 provided on the vacuum plate 212 are coupled to a radio frequency (RF) power source (not shown) and used to strike (ignite) a plasma from the plasma processing source gas released into the plasma processing chamber 202. The chuck 206 is also typically RF powered during the etch processes using an RF power supply (not shown). A pump 218 is also included to draw the process gases and gaseous products from the plasma processing chamber 202 through a duct 220.

The plasma processing system 200 includes a gas flow system 221 to control the delivery of the plasma processing source gases to the plasma processing chamber 202. The gas flow system 221 provides better control for releasing gas inside the plasma processing chamber 202. The gas flow system 221 includes a gas flow controller 222. The gas flow controller 222 receives source gas from a gas supply (not shown) through an inlet 224. The source gas can be a single gas or a mixture of gases. The gas flow controller 222 also includes outlets 226 and 228 that supply the source gas to different locations of the plasma processing chamber 202 in a controlled fashion.

The gas outlets 226 and 228 can be connected to the plasma processing chamber 202 in a manner that source gas is delivered to different regions inside the plasma processing chamber 202. By way of example, as illustrated in FIG. 2, the outlet 226 can be configured to supply source gas to a top central region within the plasma processing chamber 202, and the outlet 228 can be configured to supply source gas to an upper peripheral region of the plasma processing chamber 202. Typically, the top central region is directly above the wafer 204, and the upper peripheral region is at the walls 214 near the vacuum plate 212.

To direct the source gas to the proper locations of the plasma processing chamber 202, the plasma processing chamber 202 can utilize other mechanisms. The source gas can be supplied to the top central region where an opening in the vacuum plate 212 is provided. The source gas is thus supplied from the source gas controller 222 through the outlet 226 and then through the opening and thus into the plasma processing chamber 202. The introduction of the source gas at the upper peripheral region of the plasma processing chamber 202 is more complicated. The plasma processing system 200 includes a ring 230 that is provided between the vacuum plate 212 and the upper surface of the walls 214 of the plasma processing chamber 202. Typically, a tight seal is provided between the ring 230 and the vacuum plate 212, as well as from the upper surface of the walls 214 and the ring 230. A gas channel housing 231 is provided integral with or coupled to the ring 230. The gas channel housing 231 forms a gas channel 232 that extends around the periphery of the plasma processing chamber 202. By way of example, in one particular embodiment, 16 openings (e.g., holes) are configured at an equal distance from each other. In addition, a series of holes 234 are provided in the ring 230. These holes 234 are provided substantially equidistant about the periphery of the ring 230 and provide openings between the gas channel 232 and the upper, internal areas of the plasma processing chamber 202. The outlet 228 supplies source gas to the gas channel 232 which in turn feeds source gas through all of the holes 234, thereby supplying source gas into the plasma processing chamber 202 about the periphery (or walls) of the plasma processing chamber 202. By way of example, in one particular embodiment, 16 openings, e.g., holes are configured at an equal distance from each other.

In addition to delivering gas to different regions within the plasma processing chamber, the gas flow system 221 can also control the amount (i.e., quantity or flow rate) of the gas that is delivered to different regions. To elaborate, the gas flow system 221 can be used to determine the amount of gas supplied to a particular region inside the processing chamber. In one embodiment, the gas flow controller 222 can control the flow of source gas through each of the outlets 226 and 228. By way of example, 70% of the total volume of source gas that is received by the gas flow controller 222 can be directed by one of the outlets (e.g., outlet 226) to a first region, while the remaining 30% of the total volume of source gas can be directed by the other outlets (e.g., outlet 228) to another region. Thus, the gas flow control mechanism can be adjusted so that outlets can deliver different volumes of gas to different regions. The flow controller 222 can be implemented by a variety of known mechanisms, e.g., a system of valves, to control the amount of gas that is delivered by each gas outlet. Further, the flow controller 222 is typically controlled by a control signal 236.

The input gas that is received by the inlet 224 can be a mixture of gases that are previously combined together (e.g., pre-mixed). Alternatively, input gases can be supplied separately via two or more separate inlets, mixed at the flow controller 222, and then released as a mixture of gas into the plasma processing chamber 202 by the outlets 226, 228.

Typically, the inlet 224 receives a pre-mixed, mixture of gases with a particular gas flow rate ratio. By way of example, a mixture of a fluorocarbon gas and oxygen as the source gas can flow in the plasma processing chamber 202 via the flow controller 222 such that flow rate ratio of the fluorocarbon gas to the oxygen gas is 2:1. The gas flow system 221 can be configured to deliver the same gas mixture, i.e., with the same flow rate ratio, to multiple locations of the plasma processing chamber 202. Alternatively, the gas flow system 221 can control the flow rate ratio of gases, such that different flow rate ratios are supplied to different locations in the plasma processing chamber.

It should be noted that that in accordance with one embodiment, the gas flow system 221 can release a gas mixture that varies from the gas mixture that is received by the gas flow system 221. By way of example, if a mixture of a fluorocarbon gas and oxygen with a flow rate ratio of 1.5(fluorocarbon):to 1 (oxygen) is received by the gas flow system 221, a different flow rate ratio may be output by the gas outlets. For example, one gas outlet can release gas at a flow rate ratio of 1(fluorocarbon):to 1 (oxygen), while the other gas outlet releases gas with a flow rate ratio of 2(fluorocarbon):to 1 (oxygen), and so forth. It should be understood that gas flow rate ratios can also be adjusted so the one gas outlet delivers only a particular gas as opposed to another gas or a mixture of gases.

Thus, the gas flow system 221 allows input gases to be released to a desired region in a plasma processing chamber 202. Additionally, volume, e.g., flow rate, of gases that are released into that region can be adjusted by the gas flow system 221. Further, the gas flow system 221 provides the ability to adjust the relative flow rate ratios of different gases that are released into a plasma processing chamber. Furthermore, the amount, volume or relative flow of gas that is delivered to a particular region can be modified for different phases of the processing (e.g., etch processing). By way of example, the gas flow system 221 can set the flow rate for a plasma processing gas to one value for one stage of the etching process and then adjust the flow rate for the plasma processing gas during a subsequent state of the same etching process.

Although FIG. 2 illustrates the source gases being supplied to a top peripheral region as well as an upper peripheral region, in general, source gas can be supplied to multiple, different locations within a plasma processing chamber. As an example, source gas could be supplied to a lower peripheral region. Such source gas can be supplied into the plasma processing chamber through holes in the walls of the plasma processing chamber. As another example, gas can be supplied to a lower region around the substrate, e.g., near the edges of the wafer 204. By way of example, such source gas can be released by the ESC 206 near the edges of the wafer 204.

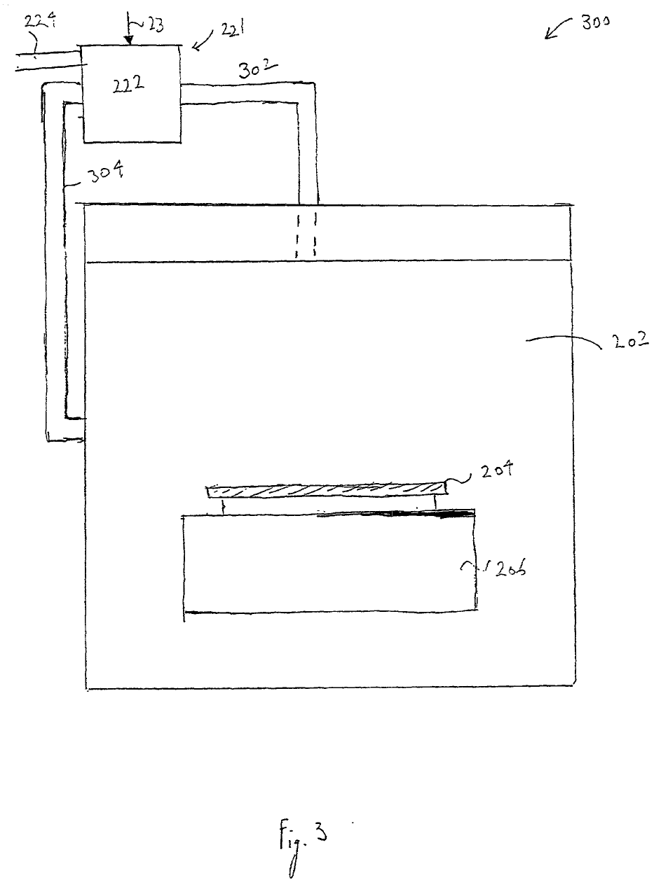

FIG. 3 depicts a simplified plasma processing system 300 suitable for delivery and release of input gases into a top peripheral region as well as lower peripheral region in accordance with another embodiment of the present invention. The plasma processing system 300 includes a gas flow system 221 to control the delivery of gas to the plasma processing chamber 202 as did the plasma processing chamber 200 of Fig. 2. In this particular embodiment, the gas flow controller 222 includes outlet 302 that supplies source gas into a top central region of the plasma processing chamber 202 and an outlet 304 that supplies source gas to a lower peripheral region of the plasma processing chamber 202 in a controlled fashion.

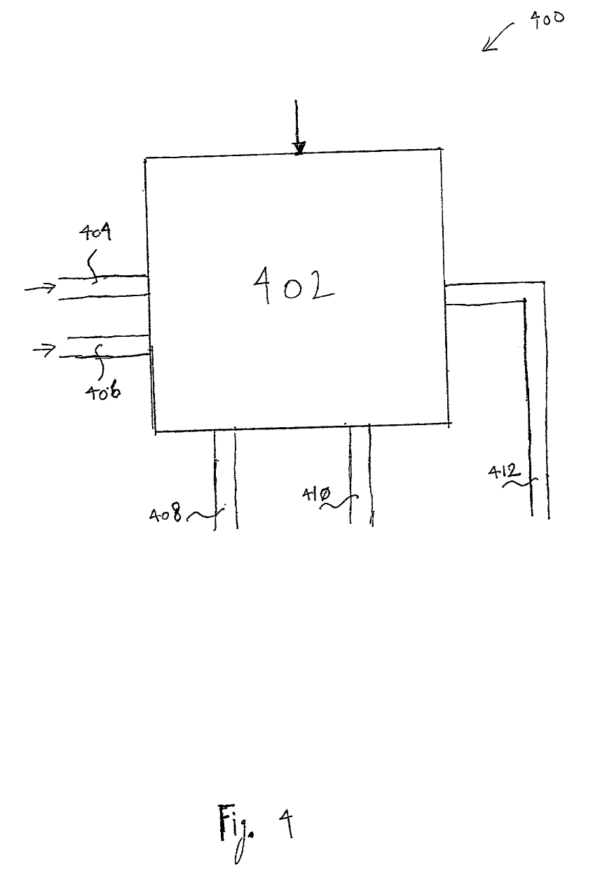

In addition, as will be apparent to those skilled in the art, if desired, more than two gas outlets can be utilized to deliver gas to a variety of different regions inside the plasma processing chamber. FIG. 4 illustrates a gas flow system 400 suitable for controlling the delivery of gas into a plasma processing chamber in accordance with another embodiment of the present invention. The gas flow system 400 includes a gas flow controller 402. The gas flow controller 402 can receive source gas through inlets 404 and 406. The source gas that is received by gas flow controller 402 can be a single gas or a mixture of gases. As shown in FIG. 4, the gas flow system 400 includes gas outlets 408, 410, and 412 which are suitable for delivery of gas into different regions of the plasma processing chamber in a control led fashion. By way of example, the gas outlets 408, 410, and 412 can be utilized to supply gas into three different regions, e.g., a top central region, an upper peripheral region, and a lower peripheral region of the plasma processing chamber 202 in a controlled fashion. In addition, the gas flow system 402 is configured to provide the ability to adjust the amount of gas that is delivered to different regions by gas outlets 408, 410, and 412.

As shown in FIG. 4, two gas inlets (404 and 406) can be utilized to receive source gas that is delivered to different regions by gas outlets 408, 410, and 412. Each of gas inlets 404 and 406 can receive a different gas or a different combination of gases. It should be understood the values for gas flow rates and/or gas flow rate ratios that are released into a region can be different than those values that are received by the gas inlets 404 and 406. In other words, the gas flow system 400 provides the ability to determine and adjust the gas flow rates for release of gas into different regions of the plasma processing chamber. By way of example, the flow rate for release of gas into one region can be different than flow rate for release of gas into a different region. In addition, the flow rates for release of gas into one or all of the regions can be different than the flow rate at which the gas is received by the gas flow system 400. It should also be noted that although the gas flow system is configured to release gas into three regions, this does not necessarily mean that gas has be released into all of the region at any particular time during the etch process. By way example, the flow to gas outlet 408 can be completely shut off during a particular point in the etch process. The flow of gas into a region can be initiated or resumed at a later time during the etch process, and so forth.

The source gases can by supplied into the plasma processing chamber 202 by a variety of mechanisms. By way of example, the source gases can be supplied by a gas ring or openings such as ports or holes that are built into walls of the plasma processing chamber 102. It should also be noted that in plasma processing systems having a gas distribution plate (GDP), source gases can be delivered from a pattern of holes provided in the GDP. Regardless of how the source gas arrives within the plasma processing chamber 202 during the etching process, the source gases are then excited to strike a plasma. The surface of the wafer 204 is etched by the plasma. In one implementation, the source gases contain a mixture of a fluorocarbon and oxygen gases. In addition to such source gases, other gases can also flow in the plasma processing chamber 102. These other gases are typically mixed with the source gases but can be separate. For example, other gases, such as Argon, may be released into the plasma processing chamber 202 to serve as a dilutant, or a deposition precursor.

As it will be understood by those skilled in the art, the invention may be practiced in a number of other suitably arranged processing chambers. For example, the invention is applicable to processing chambers that deliver energy to the plasma through capacitively coupled parallel electrode plates, through inductively coupled RF sources such as helicon, helical resonators, and transformer coupled plasma (TCP). TCP plasma processing systems are available from Lam Research Corporation of Fremont, Calif. Other examples of suitable processing chambers include an inductive plasma source (IPS), a decoupled plasma source (DPS), and a dipole ring magnet (DRM).

As noted in the background, fabrication of modern integrated circuits continues to challenge those skilled in the art to gain better control over the etching process. By way of example, an important etching process parameter is the distribution of plasma inside the plasma processing chamber. To elaborate, as is known in the art, plasma processing conditions are associated with both charged and neutral components. As is well known, the charged components, e.g., positive and negative gas ions, significantly effect the etching process. The neutral components can also effect the etching process, e.g., some of the neutral gas components may react with the substrate wafer, other neutral components may stick to the walls of the processing chamber, etc. Thus, control over the distribution of the neutral plasma component is also desirable since it could significantly improve the etching process. In addition, it would be very desirable to provide for plasma processing systems and methods that are capable of enhancing control over the distribution of both the neutral and charged components. As is appreciated by those skilled in the art, the ability to control the distribution of both the neutral and charged components would significantly improve the etching process.

Furthermore, it is also desirable to gain better control over the distribution of plasma without having to limit certain etch processing parameters. To elaborate, certain parameters can effect the distribution of plasma components. These parameters include power profile, pressure at which the processing chamber operates, product specifications and sticking coefficients of various material that make up the wafer substrate. Although distribution of plasma components can be effected by one or more of these parameters, it would be disadvantageous to attempt to gain better control over the distribution of plasma by limiting these parameters. By way of example, limiting the materials that are used to form the wafer would be highly undesirable.

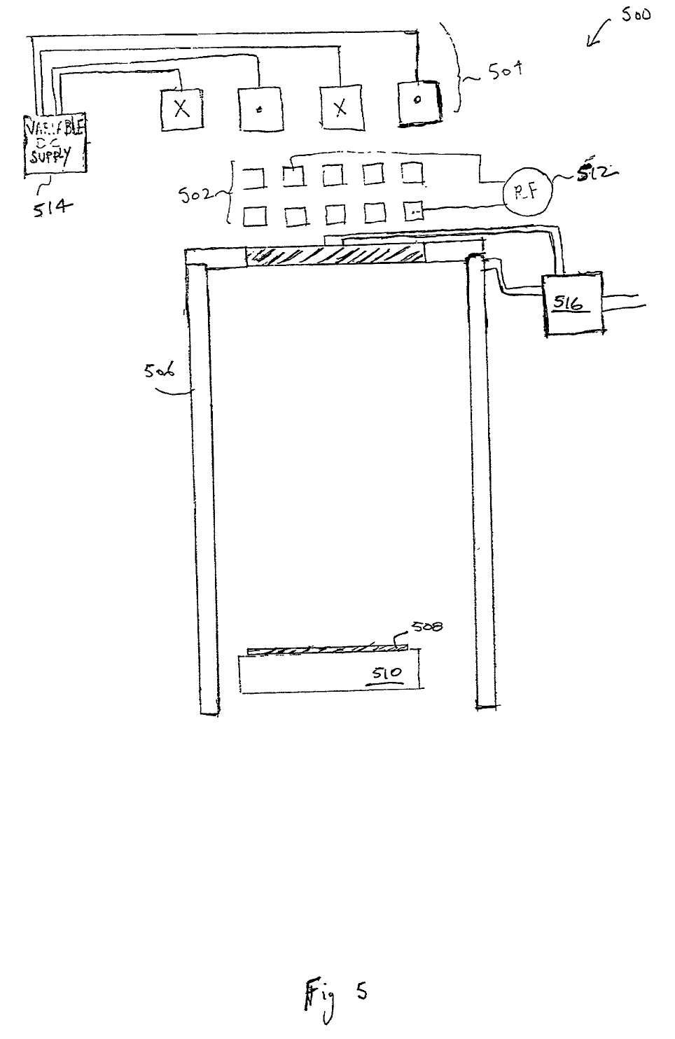

FIG. 5 illustrates, in accordance with yet another embodiment of the present invention, a plasma processing system 500 that is capable of providing better control over the distribution of both neutral and charged components. The plasma processing system 500 includes an exemplary RF antenna arrangement 502 and an exemplary upper magnet arrangement 504. In the example of FIG. 5, RF antenna arrangement 502 and upper magnet arrangement 504 are shown disposed above a plasma processing chamber 506. A wafer 500 is disposed on a chuck 510 inside the plasma processing chamber 506. As discussed in co-pending U.S. patent application Ser. No. ______ (Att. Dkt. No. LAM1P122), filed concurrently herewith, and entitled IMPROVED PLASMA PROCESSING SYSTEMS AND METHODS THEREFOR” (hereafter “referenced application”), other positions are also possible for RF antenna arrangement 502 and upper magnet arrangement 504.

RF antenna arrangement 502 is shown coupled to an RF power supply 512, which may supply RF antenna arrangement 502 with RF energy having a frequency in the range of about 0.4 MHz to about 50 MHz. In this particular embodiment, upper magnet arrangement 504 includes two concentric magnetic coils, both of which carry DC currents running in opposite directions. Upper magnet arrangement 504 is shown coupled to a variable Direct Current (DC) power supply 514, which is configured to vary the magnitude and/or direction of the direct current(s) supplied to the electromagnet coil(s) of upper magnet arrangement 504. It should be noted that other arrangements are also possible for plasma processing system 500. For example, magnetic buckets arrangements (not shown) may also be oriented around the outer periphery of the plasma processing chamber, as described in the referenced application.

The magnetic arrangement of the plasma processing system 500, or other magnetic arrangements as described in the referenced application, can significantly enhance etching process control. More particularly, among other things, the magnetic arrangement effects the distribution of charged components to provide more control over the plasma distribution. More control over the plasma distribution in turn enhances control over the etching process. Unfortunately, unlike the charged components, the neutral components do not significantly respond to magnetic fields.

As illustrated in FIG. 5, a gas flow system 516 can be used in conjunction with the magnetic arrangement 504. The gas flow system 516 can be utilized to provide more control over the distribution of neutral gas components. This in turn allows for further enhancement of control for the etch process. By way of example, gas flow system 516 can be utilized to deliver gas to different regions of the plasma processing chamber, e.g., in a similar manner as described with respect to the plasma processing system 200 shown in FIG. 2. In addition, the gas flow system 516 is configured to provide the ability to adjust the amount of gas that is delivered to a particular region. Thus, the use of the gas flow system 516 with a magnetic arrangement such as those described in the referenced application, can provide even more control of the etch process.

It is believed that distribution of neutral components can be effected by varying the time, e.g., mean time that input gases spent in the plasma processing chamber and/or the time, e.g., mean time that input gases spent in “hot zones”. Hot zones as used herein, refer to the regions where input gases are excited. By way of example, input gases can be excited in regions that are near the top surfaces of the plasma processing chamber. By providing the ability to vary the location and the amount of gas that is delivered to the processing chamber, it is possible to adjust the time that neutral components spend in the plasma processing chamber and/or in the hot zones. By way of example, the mean time that is spend in the processing chamber is typically longer for a gas particles that are released into upper regions of the plasma processing chamber. In comparison, the mean time that is spend in the processing chamber is typically shorter for a gas that is released into a lower portion of the plasma processing since it is more likely that the gas would be quickly evacuated from the processing chamber.

This invention has numerous advantages. One advantage is that the present invention operates to enhance control over the distribution of neutral and/or plasma components to provide better control over the etching process. Another advantage is that more control over the etch process can be achieved without having to limit certain other parameters, e.g., pressure, power profile, etc. Yet another advantage is that the present invention can provide the flexibility to vary distribution of neutral and/or plasma components for different etch processes, as well as during different stages of the same etching process.

As it will be appreciated by those skilled in the art, the present invention can be utilized to form a variety of etched features such as contacts, via interconnection, and etc. Further, as will be understood by those skilled in the art, the present invention can also be used in conjunction with a variety of particular etching techniques such as dual damascene, planarization, photoresist stripping, chamber cleaning, etc.

Although only a few embodiments of the present invention have been described in detail, it should be understood that the present invention may be embodied in many other specific forms without departing from the spirit or scope of the invention. Therefore, the present examples are to be considered as illustrative and not restrictive, and the invention is not to be limited to the details given herein, but may be modified within the scope of the appended claims.

What is claimed is:

1. A plasma processing system, said plasma processing system comprising:
a plasma processing chamber used to process a substrate; and
a gas flow system coupled to said plasma processing chamber, said gas flow system controlling flow of input gas into at least two different regions of said plasma processing chamber.

2. A plasma processing system as recited in claim 1, wherein the at least two different regions include a top central region and an upper peripheral region.

3. A plasma processing system as recited in claim 1, wherein the at least two different regions include a top central region and a lower peripheral region.

4. A plasma processing system as recited in claim 1, wherein the at least two different regions include a top central region, a lower peripheral region, and an upper peripheral region.

5. A plasma processing system as recited in claim 1, wherein the at least two different regions include a lower region near the substrate.

6. A plasma processing system as recited in claim 1, wherein the plasma processing system includes a chuck and the least two different regions include a lower region near edges of the substrate, and
wherein the input gas is released through the chuck.

7. A plasma processing system as recited in claim 1, wherein said flow system controls amount or volume of the input gas into the at least two different regions of said plasma processing chamber.

8. A plasma processing system as recited in claim 1, wherein said flow system controls flow rate of the input gas into the at least two different regions of said plasma processing chamber.

9. A plasma processing system as recited in claim 1, wherein the input gas includes at least first and second gases, and
wherein said flow system independently controls relative flow rate of the at least first and second gases into the at least two different regions of said plasma processing chamber.

10. A plasma processing system as recited in claim 1,
wherein said plasma processing system further comprises a gas delivery ring that is coupled to said plasma processing chamber, and
wherein said flow system controls amount or volume of the input gas to said gas delivery ring, thereby supplying the input gas to a peripheral region of said plasma processing chamber.

11. A plasma processing system as recited in claim 10, wherein said gas delivery ring is provided on an upper portion of the plasma processing chamber, thereby the gas delivery ring supplying the input gas to an upper peripheral region of said plasma processing chamber.

12. A plasma processing system as recited in claim 1, wherein said plasma processing chamber includes at least an inner wall, and the gas flow system comprises:
at least one gas inlet for receiving the input gas that is to be delivered into said plasma processing chamber;
at least first and second gas outlets that are each capable of delivering the input gas to the plasma processing system; and
wherein at least a portion of the input gas is delivered to the plasma processing chamber via said first and second gas outlets.

13. A plasma processing system as recited in claim 12, wherein the at least a portion of the input gas is released into a second region, the first region being a top central region within the plasma processing chamber, and the input gas that is released into the first region is delivered by the first gas outlet.

14. A plasma processing system as recited in claim 12, wherein the at least a portion of the input gas is released into a second region, the first region being an upper peripheral region that surrounds the inner wall of the plasma processing chamber, and the input gas that is released into the second region is delivered by the second gas outlet.

15. A plasma processing system as recited in claim 12, wherein the at least a portion of the input gas is released into a second region, the second region being a lower peripheral region that surrounds the inner wall of the plasma processing chamber, and the input gas that is released into the second region is delivered by the second gas outlet.

16. A plasma processing system as recited in claim 12, wherein the gas flow system receives a gas flow control signal for determining the amount or volume of the input gas that is delivered into the plasma processing chamber by each one of the first and second gas outlets.

17. A plasma processing system as recited in claim 16, wherein the gas flow control signal determines the flow rate of delivery of gas by each of the first and second gas outlets into the plasma processing chamber.

18. A plasma processing system as recited in claim 16, wherein the input gas includes at least first and second gases, and
wherein said flow control signal independently determines relative flow rate of the at least first and second gases into the at least two different regions of said plasma processing chamber.

19. A plasma processing system for processing a substrate, comprising:
a substantially cylindrical plasma processing chamber within which a plasma is both ignited and sustained for said processing, said plasma processing chamber having no separate plasma generation chamber, said plasma processing chamber having an upper end and a lower end;
a coupling window disposed at an upper end of said plasma processing chamber.
an RF antenna arrangement disposed above a plane defined by said substrate when said substrate is disposed within said plasma processing chamber for said processing;
an electromagnet arrangement disposed above said plane defined by said substrate, said electromagnet arrangement being configured so as to result in a radial variation in the static magnetic field topology within said plasma processing chamber in the region proximate said RF antenna when at least one direct current is supplied to said electromagnet arrangement, said radial variation being effective to affect processing uniformity across said substrate;
a dc power supply coupled to said electromagnet arrangement, said dc power supply having a controller to vary a magnitude of said at least one direct current, thereby changing said radial variation in said magnetic field topology within said plasma processing chamber in said region proximate said antenna to improve said processing uniformity across said substrate; and
a gas flow system coupled to said plasma processing chamber, said gas flow system controlling flow of input gas into at least two different regions of said plasma processing chamber.

20. A plasma processing system as recited in claim 19, wherein the at least two different regions include a top central region and an upper peripheral region.

21. A plasma processing system as recited in claim 19, wherein the at least two different regions include a top central region and a lower peripheral region.

22. A plasma processing system as recited in claim 19, wherein the at least two different regions include a top central region, a lower peripheral region, and an upper peripheral region.

23. A plasma processing system as recited in claim 19, wherein said flow system control s amount or volume of the input gas into the at least two different regions of said plasma processing chamber.

24. A plasma processing system as recited in claim 19, wherein said flow system controls flow rate of the input gas into the at least two different regions of said plasma processing chamber.

25. A plasma processing system as recited in claim 19, wherein the input gas includes at least first and second gases, and
wherein said flow system independently controls relative flow rate of the at least first and second gases into the at least two different regions of said plasma processing chamber.

26. A plasma processing system as recited in claim 19, wherein said plasma processing system further comprises a gas delivery ring that is coupled to said plasma processing chamber, and
wherein said flow system controls amount or volume of the input gas to said gas delivery ring, thereby supplying the input gas to a peripheral region of said plasma processing chamber.

27. A plasma processing system as recited in claim 26, wherein said gas delivery ring is provided on an upper portion of the plasma processing chamber, thereby the gas delivery ring supplying the input gas to an upper peripheral region of said plasma processing chamber.

28. A plasma processing system as recited in claim 19, wherein said plasma processing chamber includes at least an inner wall, and the gas flow system comprises:
at least one gas inlet for receiving the input gas that is to be flown into said plasma processing chamber;
at least first and second gas outlets that are each capable of delivering the input gas to the plasma processing system; and
wherein at least a portion of the input gas is delivered to the plasma processing chamber via said first and second gas outlets.

29. A plasma processing system as recited in claim 28, wherein the at least a portion of the input gas is released into a second region, the first region being a top central region within the plasma processing chamber, and the input gas that is released into the first region is delivered by the first gas outlet.

30. A plasma processing system as recited in claim 28, wherein the at least a portion of the input gas is released into a second region, the first region being an upper peripheral region that surrounds the inner wall of the plasma processing chamber, and the input gas that is released into the second region is delivered by the second gas outlet.

31. A plasma processing system as recited in claim 28, wherein the at least a portion of the input gas is released into a second region, the second region being a lower peripheral region that surrounds the inner wall of the plasma processing chamber, and the input gas that is released into the second region is delivered by the second gas outlet.

32. A plasma processing system as recited in claim 28, wherein the gas flow system receives a gas flow control signal for determining the amount or volume of the input gas that is delivered into the plasma processing chamber by each one of the first and second gas outlets.

33. A plasma processing system as recited in claim 32, wherein the gas flow control signal determines the flow rate of delivery of gas by each of the first and second gas outlets into the plasma processing chamber.

34. A plasma processing system as recited in claim 32, wherein the input gas includes at least first and second gases, and
wherein said flow control signal independently determines relative flow rate of the at least first and second gases into the at least two different regions of said plasma processing chamber.

35. A plasma processing system as recited in claim 19, wherein the at least two different regions include a lower region near the substrate.

36. A plasma processing system as recited in claim 19, wherein the plasma processing system includes a chuck and the least two different regions include a lower region near edges of the substrate, and
wherein the input gas is released through the chuck.

37. A plasma processing system for processing a substrate, comprising:
a substantially cylindrical plasma processing chamber within which a plasma is both ignited and sustained for said processing, said plasma processing chamber having no separate plasma generation chamber, said plasma processing chamber having an upper end and a lower end;
a coupling window disposed at an upper end of said plasma processing chamber.
an RF antenna arrangement disposed above a plane defined by said substrate when said substrate is disposed within said plasma processing chamber for said processing;
an electromagnet arrangement disposed above said plane defined by said substrate, said electromagnet arrangement being configured so as to result in a radial variation in the static magnetic field topology within said plasma processing chamber in the region proximate said RF antenna when at least one direct current is supplied to said electromagnet arrangement, said radial variation being effective to affect processing uniformity across said substrate;
a dc power supply coupled to said electromagnet arrangement, said dc power supply having a controller to vary a magnitude of said at least one direct current, thereby changing said radial variation in said magnetic field topology within said plasma processing chamber in said region proximate said antenna to improve said processing uniformity across said substrate; and
a gas flow system coupled to said plasma processing chamber, wherein the gas flow system controls the input gas is released into a first and a second region within the plasma processing chamber, the first region being a top central region within the plasma processing chamber and the second region being a peripheral region of the plasma processing chamber.
